(19) United States
(12) Patent Application Publication
(10) Pub. No.: US 2009/0284266 A1
(43) Pub. Date: Nov. 19, 2009

(54) Test method and device for land grid array components

(76) Inventor: Kuan-Hsing Li, Taichung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/153,287

(22) Filed: May 16, 2008

(51) Int. Cl. G01R 31/02

(52) U.S. Cl. 324/537

(57) ABSTRACT

A test method for Land Grid Array components includes the steps of: providing a test board with a plurality of test points; providing a secondary test board which has a plurality of conductors extending therethrough from a top surface to a bottom surface and forms a drop thereon, placing the secondary test board on the test board and contacting the conductors with the test points correspondingly; disposing a conducting spacer on the secondary test board, which is contacted with the conductors of the secondary test board correspondingly; and placing a test object on the conducting spacer, which has a plurality of conducting terminals contacted with the conducting spacer, and pressing the test object downwards so that the conducting terminals, the conducting spacer, the conductors and the test points are electrically connected for testing the test object. A test device for Land Grid Array components also is provided.

### BACKGROUND OF THE INVENTION

1. Field of the Invention

The present invention relates to a test method and device, and more especially to a test method and device for electronic parts with Land Grid Array (LGA) components.

2. Description of Related Art

Most of conventional test fixtures for SMT parts (test objects) with LGA components are electrically connected to the test objects and test boards via probes or conducting spacers. Though the probes have good contact performance, they are easily damaged and need to be replaced frequently. Besides, the probes have high cost. The conducting spacers have lower cost than the probes and aren't damaged easily, but they have bad contact with the test objects with flat surfaces so that it is necessary to exert large forces on the test objects to test.

Please refer to FIG. 1 and FIG. 2, a prior test device with a conducting spacer is disclosed. The test device disposes a conducting spacer 8 on a test board 7. The conducting spacer 8 is made of conductive rubber and includes an insulating soft rubber layer 81 and a plurality of conducting wires 82 vertically extending through the insulating soft rubber layer 81 from up to down. Lower ends of the conducting wires 82 contact with a plurality of test points on a top surface of the test board 7 correspondingly. A test object 9 is placed on a top surface of the conducting spacer 8. The test object 9 has a plurality of conducting terminals 91 on a bottom surface thereof, which correspondingly contact with upper ends of the conducting wires 82. When a test fixture presses the test object 9 downwards, the conducting spacer 8 electrically connects the test object 9 with the test board 7, thereby testing the test object 9. However, the conducting spacer 8 has bad contact with the test object 9 with flat surfaces, so it is necessary to exert a large force on the test object 9 to test. If the test object 9 has a ceramics substrate, it tends to be damaged under pressure.

Hence, the inventors of the present invention believe that the shortcomings described above are able to be improved and finally suggest the present invention which is of a reasonable design and is an effective improvement based on deep research and thought.

### SUMMARY OF THE INVENTION

The object of the present invention is to provide a test method and device for Land Grid Array components which can improve contact performance and reduce pressure exerted by a fixture, thereby avoiding damaging a test object under pressure.

To achieve the above-mentioned object, a test method for Land Grid Array components in accordance with the present invention is provided. The test method includes the steps of: providing a test board with a plurality of test points; providing a secondary test board which has a plurality of conductors extending through the secondary test board from a top surface to a bottom surface and forms a drop from portions on which the conductors are disposed to the other portions of the secondary test board, placing the secondary test board on the test board, and contacting one end of each conductor with a corresponding test point; disposing a conducting spacer on the secondary test board, which is contacted with the other end of each conductor correspondingly; and placing a test object on the conducting spacer, which has a plurality of conducting terminals contacted with the conducting spacer, and then pressing the test object downwards so that the conducting terminals of the test object, the conducting spacer, the conductors of the secondary test board and the test points of the test board are electrically connected for testing the test object.

The present invention also provides a test device for Land Grid Array components. The test device includes a test board with a plurality of test points and a secondary test board having a plurality of conductors corresponding to the test points. The conductors extend through the secondary test board from a top surface to a bottom surface. The secondary test board forms a drop from portions on which the conductors are disposed to the other portions thereof. The secondary test board is placed on the test board and one end of each conductor is contacted with a corresponding test point.

The present invention is advantageous that the secondary test board of the present invention brings a drop to the test board so that the pressure on the conducting spacer can be concentrated on the conducting terminals of the test object, thereby improving contact performance, reducing pressure exerted by a fixture, and avoiding damaging the test object under pressure.

To further understand features and technical contents of the present invention, please refer to the following detailed description and drawings related the present invention. However, the drawings are only to be used as references and explanations, not to limit the present invention.

### BRIEF DESCRIPTION OF THE DRAWINGS

FIG. 1 is a plan view of a prior test device;

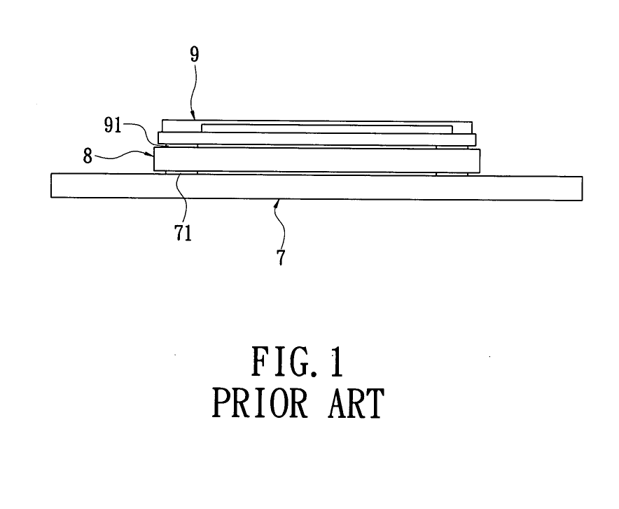

FIG. 2 is a perspective view of the prior test device;

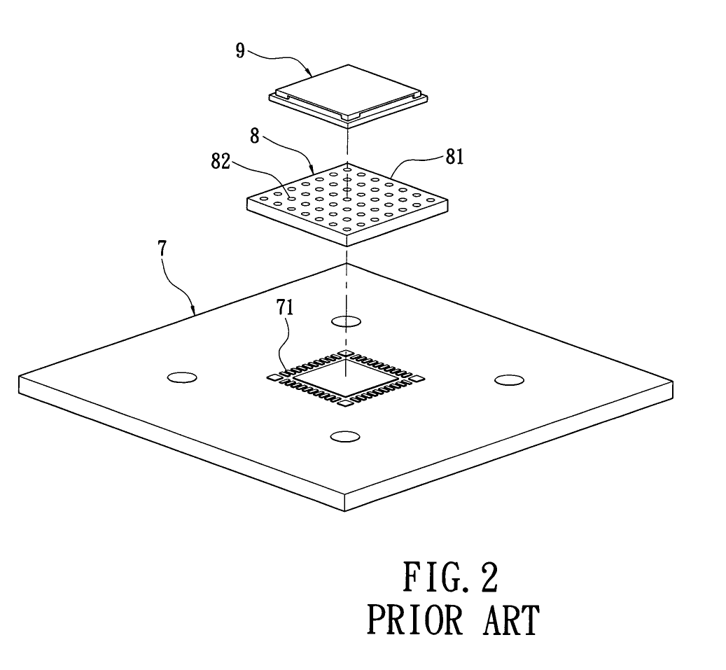

FIG. 3 is a plan view of a test device for Land Grid Array components according to the present invention;

FIG. 4 is a perspective view of the test device for Land Grid Array components according to the present invention;

FIG. 4A is a cross-sectional view of a conductor of a secondary test board of the present invention; and

FIG. 5 is a flow chart of a test method for Land Grid Array components according to the present invention.

### DETAILED DESCRIPTION OF THE PREFERRED EMBODIMENTS

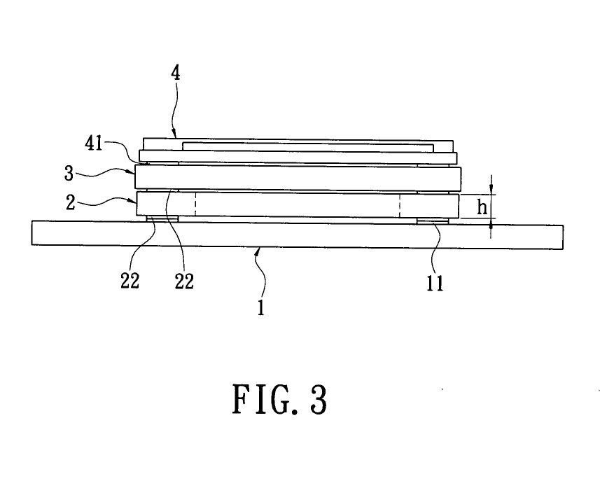

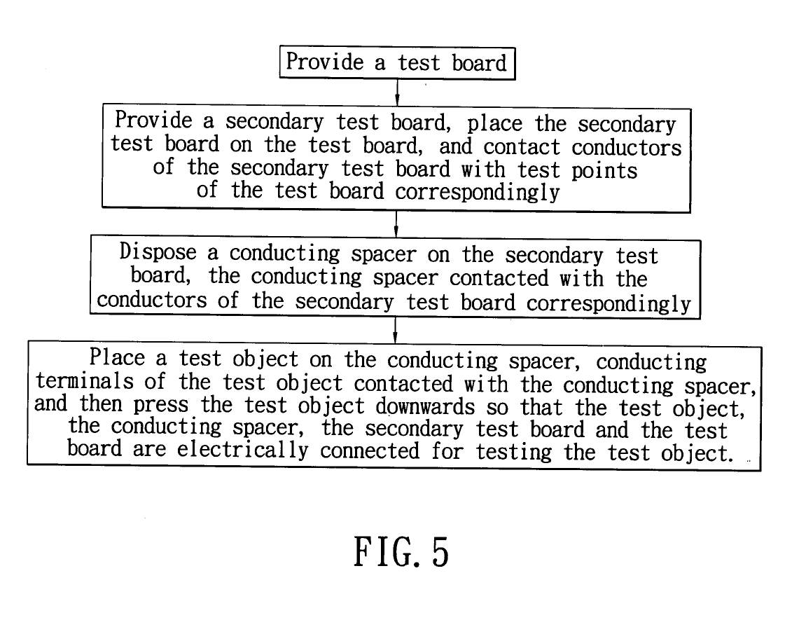

Please refer to FIGS. 3-5, the present invention provides a test method for Land Grid Array components, and more especially provides a test method for an electronic part (a test object) with Land Grid Array components. The method includes the steps of:

(1) Firstly, providing a test board 1 which has a plurality of test points 11 on a top surface thereof, corresponding to a plurality of conducting terminals 41 on a bottom surface of the test object 4.

(2) Providing a secondary test board 2 which has a quadrate hollow-out portion 21 thereinside and a plurality of conductors 22 around the hollow-out portion 21 thereon, wherein the hollow-out portion 21 extends through the secondary test board 2 from a top surface to a bottom surface, and the plurality of conductors 22 correspond to the plurality of test points 11 and extend through the secondary test board 2 from the top surface to the bottom surface. In the embodiment, the secondary test board 2 forms the hollow-out portion 21 to create a drop of h from the portions on which the conductors 22 are disposed to the other portions of the secondary test board 2. Alternatively, the secondary test board 2 also may define a groove (not shown) and so on to replace the hollow-out portion 21, thereby forming a drop of h from the portions on which the conductors 22 are disposed to the other portions of the secondary test board 2.

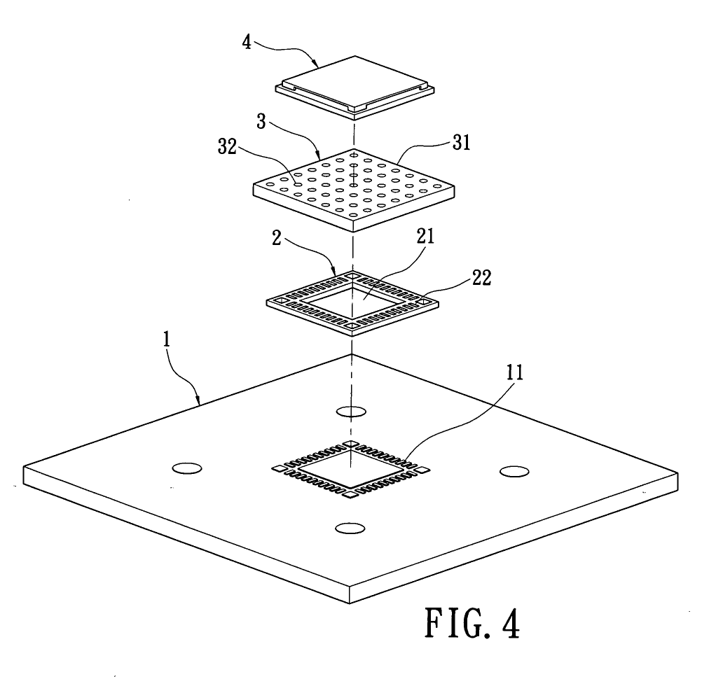

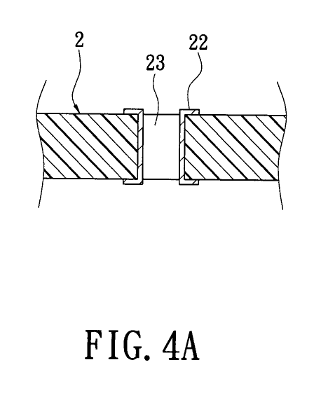

In the embodiment, the conductors 22 are formed by drilling a plurality of perforated holes 23 (as shown in FIG. 4A) in the secondary test board 2, corresponding to the plurality of test points 11, and electroplating inner walls of the perforated holes 23. So the conductors 22 have metal coating structure.

Place the secondary test board 2 on the top surface of the test board 1, contact lower ends of the conductors 22 with the corresponding test points 11, and then weld the lower ends of the conductors 22 and the test points 11 together by SMT, so that the conductors 22 and the test points 11 are electrically connected to form a test device for Land Grid Array components.

(3) Disposing a conducting spacer 3 on the secondary test board 2, wherein the conducting spacer 3 is made of a conductive rubber and includes an insulating soft rubber layer 31 and a plurality of conducting wires 32 vertically extending through the insulating soft rubber layer 81 from up to down, and lower ends of the conducting wires 32 are contacted with upper ends of the conductors 22 of the secondary test board 2 correspondingly, thereby the conducting spacer 3 is electrically connected with the test board 1 via the secondary test board 2.

(4) Placing the test object 4 on a top surface of the conducting spacer 3, wherein the test object 4 has a plurality of conducting terminals 41 on a bottom surface thereof, which are correspondingly contacted with upper ends of the conducting wires 32; and then pressing the test object 4 downwards via a fixture, so that the conducting terminals 41 of the test object 9, the conducting wires 32 of the conducting spacer 3, the conductors 22 of the secondary test board 2 and the test points 11 of the test board 1 are electrically connected, thereby testing the test object 4.

The present invention specially disposes the secondary test board 2 between the test board 1 and the conducting spacer 3 and the secondary test board 2 brings a drop to the test board 1, so that the pressure on the conducting spacer 3 can be concentrated on the conducting terminals 41 of the test object 4, thereby improving contact between the conducting spacer 3 and the test object 4. Since the pressure is concentrated on the conducting terminals 41 of the test object 4, pressure exerted by a fixture can be reduced and the test object 4 can be avoided being damaged under pressure.

What is disclosed above is only the preferred embodiment of the present invention and it is therefore not intended that the present invention be limited to the particular embodiments disclosed. It will be understood by those skilled in the art that various equivalent changes may be made depending on the specification and the drawings of present invention without departing from the scope of the present invention.

What is claimed is:

1. A test method for Land Grid Array components, comprising the steps of:
providing a test board with a plurality of test points;
providing a secondary test board which has a plurality of conductors corresponding to the test points, wherein the conductors extend through the secondary test board from a top surface to a bottom surface and the secondary test board forms a drop from portions on which the conductors are disposed to the other portions thereof, placing the secondary test board on the test board, and contacting one end of each conductor with a corresponding test point;
disposing a conducting spacer on the secondary test board, the conducting spacer contacted with the other end of each conductor correspondingly; and
placing a test object on the conducting spacer, the test object having a plurality of conducting terminals contacted with the conducting spacer, and pressing the test object downwards so that the conducting terminals of the test object, the conducting spacer, the conductors of the secondary test board and the test points of the test board are electrically connected for testing the test object.

2. The test method for Land Grid Array components as claimed in claim 1, wherein the secondary test board forms a hollow-out portion thereinside, which extends through the secondary test board from the top surface to the bottom surface thereby the secondary test board forms the drop.

3. The test method for Land Grid Array components as claimed in claim 1, wherein the secondary test board has a plurality of perforated holes corresponding to the test points, and inner walls of the perforated holes are electroplated to form the conductors.

4. The test method for Land Grid Array components as claimed in claim 1, wherein the end of each conductor and the corresponding test point are welded.

5. The test method for Land Grid Array components as claimed in claim 1, wherein the conducting spacer includes an insulating soft rubber layer and a plurality of conducting wires vertically extending through the insulating soft rubber layer from up to down, and one end of each conducting wire is contacted with the other end of the corresponding conductor and the other end of each conducting wire is contacted with a correspond conducting terminal.

6. A test device for Land Grid Array components, comprising:
a test board with a plurality of test points; and
a secondary test board having a plurality of conductors corresponding to the test points, wherein the conductors extend through the secondary test board from a top surface to a bottom surface and the secondary test board forms a drop from portions on which the conductors are disposed to the other portions thereof, and the secondary test board is placed on the test board and one end of each conductor is contacted with a corresponding test point.

7. The test device for Land Grid Array components as claimed in claim 6, wherein the secondary test board forms a hollow-out portion thereinside, which extends through the secondary test board from the top surface to the bottom surface thereby the secondary test board forms the drop.

8. The test device for Land Grid Array components as claimed in claim 6, wherein the secondary test board has a plurality of perforated holes corresponding to the test points, and inner walls of the perforated holes are electroplated to form the conductors.

9. The test device for Land Grid Array components as claimed in claim 6, wherein the end of each conductor and the corresponding test point are welded.

10. The test device for Land Grid Array components as claimed in claim 6, further comprising a conducting spacer disposed on the secondary test board and contacted with the other end of each conductor correspondingly.

11. The test device for Land Grid Array components as claimed in claim 10, wherein the conducting spacer is adapted for being placed a test object on, which has a plurality of conducting terminals contacted with the conducting spacer.

12. The test device for Land Grid Array components as claimed in claim 11, wherein the conducting spacer includes an insulating soft rubber layer and a plurality of conducting wires vertically extending through the insulating soft rubber layer from up to down, and one end of each conducting wire is contacted with the other end of the corresponding conductor and the other end of each conducting wire is contacted with a correspond conducting terminal.
